(19) United States
(12) Patent Application Publication
(10) Pub. No.: US 2025/0373229 A1
(43) Pub. Date: Dec. 4, 2025

(54) SURFACE ACOUSTIC WAVE (SAW) DEVICE WITH BARRIER LAYERS BETWEEN ALUMINUM-COPPER LAYERS

(71) Applicant: RF360 Singapore Pte. Ltd., Singapore (SG)

(72) Inventors: Marc Konstantin DIETRICH, Munich (DE); Tomasz JEWULA, Markt Schwaben (DE); Matthias HONAL, Munich (DE)

(21) Appl. No.: 18/677,413

(22) Filed: May 29, 2024

(51) Int. Cl. H03H 9/145; H03H 3/08; H03H 9/25; H03H 9/64

(52) U.S. Cl. CPC H03H 9/14541; H03H 3/08; H03H 9/25; H03H 9/6483

(57) ABSTRACT

Certain aspects of present disclosure are directed towards a surface acoustic wave (SAW) device. The SAW device may include a piezoelectric layer and an interdigital transducer (IDT) disposed above the piezoelectric layer and comprising an electrode including: a first aluminum (Al)-copper (Cu) layer; a second Al—Cu layer; a first barrier layer between the first Al—Cu layer and the second Al—Cu layer; a third Al—Cu layer; and a second barrier layer between the second Al—Cu layer and the third Al—Cu layer.

### TECHNICAL FIELD

Certain aspects of the present disclosure relate generally to electronic components and, more particularly, to surface acoustic wave (SAW) devices implemented with one or more barrier layers.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high frequency (e.g., generally greater than 100 MHZ) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as cellular phones).

Today, surface acoustic wave (SAW) or bulk acoustic wave (BAW) components may be used in wireless communication devices, such as for implementing RF filters, In SAW technology, the acoustic wave propagates laterally on a surface of a piezoelectric substrate (or a piezoelectric layer in examples where there are additional layers below the piezoelectric layer), with the movement of the piezoelectric generated by metal interdigitated transducers (IDTs) on the surface. The wavelength of the acoustic wave may be defined by the pitch (e.g., the spacing between fingers, which may be defined as the width of the metal finger and gap from one edge of a finger to a corresponding edge on an adjacent finger) of the IDT. In BAW technology, the acoustic wave propagates vertically through a three-dimensional structure, with an electric field applied through electrodes above and below a piezoelectric material. The wavelength, in this case, is defined by the thickness of the piezoelectric material.

In some types of SAW devices, a surface acoustic wave is generated by an input IDT and detected by an output IDT. In other types of SAW devices, the acoustic energy may be confined using reflectors on either side of the IDT. A planar resonant cavity created between two mirrors consisting of reflecting metal strips can also be used to trap the acoustic energy.

As the number of frequency bands used in wireless communications increases and as the desired frequency band of filters widens, the performance of acoustic filters increases in importance to reduce losses and increase overall performance of electronic devices. Acoustic filters with improved performance, particularly filters with reduced mechanical losses and self-heating, are therefore sought after.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include implementation of one or more barrier layers to limit aluminum (Al) copper grain growth in surface acoustic wave (SAW) technology.

Certain aspects of present disclosure are directed towards a surface acoustic wave (SAW) device. The SAW device may include a piezoelectric layer and an interdigital transducer (IDT) disposed above the piezoelectric layer and comprising an electrode including: a first aluminum (Al)-copper (Cu) layer; a second Al—Cu layer; a first barrier layer between the first Al—Cu layer and the second Al—Cu layer; a third Al—Cu layer; and a second barrier layer between the second Al—Cu layer and the third Al—Cu layer.

Certain aspects of present disclosure are directed towards a method of fabricating a SAW device. The method generally includes forming an interdigital transducer (IDT) disposed above a piezoelectric layer, wherein forming the IDT comprises forming an electrode, and wherein the forming the electrode includes: forming a first Al—Cu layer; forming a first barrier layer; forming a second Al—Cu layer such that the first barrier layer is between the first Al—Cu layer and the second Al—Cu layer; forming a second barrier layer; and forming a third Al—Cu layer such that the second barrier layer is between the second Al—Cu layer and the third Al—Cu layer.

Certain aspects of present disclosure are directed towards a wireless device. The wireless device may include a radio frequency (RF) circuit and a surface acoustic wave (SAW) filter coupled to the RF circuit, the SAW filter comprising a piezoelectric layer and an interdigital transducer (IDT) disposed above the piezoelectric layer and comprising an electrode including: a first aluminum (Al)-copper (Cu) layer; a second Al—Cu layer; a first barrier layer between the first Al—Cu layer and the second Al—Cu layer; a third Al—Cu layer; and a second barrier layer between the second Al—Cu layer and the third Al—Cu layer.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1A is a perspective view of an example electroacoustic device, in which certain aspects of the present disclosure may be practiced.

FIG. 1B is a cross-sectional view of the example electroacoustic device of FIG. 1A.

FIG. 2A is a top view of an example electrode structure of an electroacoustic device, in which certain aspects of the present disclosure may be practiced.

FIG. 2B is a top view of another example electrode structure of an electroacoustic device, in which certain aspects of the present disclosure may be practiced.

FIGS. 3A and 3B illustrate an electroacoustic device, in which certain aspects of the present disclosure may be practiced.

FIG. 4 illustrates an example electrode for a surface acoustic wave (SAW) device, in accordance with certain aspects of the present disclosure.

FIG. 5 illustrates another example electrode for a SAW device, in accordance with certain aspects of the present disclosure.

FIG. 6A illustrates grain size growth for an electrode implemented without a barrier layer, in accordance with certain aspects of the present disclosure.

FIG. 6B illustrates an electrode implemented with a barrier layer, in accordance with certain aspects of the present disclosure.

FIG. 7 illustrates an electrode with four layers with varying Cu content and with barrier layers in between, in accordance with certain aspects of the present disclosure.

FIG. 8 is a block diagram of example operations for fabricating a SAW device, in accordance with certain aspects of the present disclosure.

FIG. 9 is a schematic diagram of an electroacoustic filter circuit.

FIG. 10 is a functional block diagram of at least a portion of an example simplified wireless transceiver circuit in which the filter circuit of FIG. 9 may be employed.

FIG. 11 is a diagram of an environment that includes an electronic device that includes a wireless transceiver such as the transceiver circuit of FIG. 10.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to a surface acoustic wave (SAW) device implemented with multiple layers separated by diffusion barriers (e.g., also referred to as “intermediate layers”). The SAW device may be implemented with a multilayer electrode stack for implementing an interdigitated transducer (IDT) for a SAW resonator/filter. The multilayer electrode may include two or more aluminum (Al)-copper (Cu) layers (e.g., diffused copper and aluminum) sandwiched between barrier layers (e.g., thin titanium layers). Certain aspects of the present disclosure improve the power durability of the SAW device. The SAW device provided herein may include multiple Al—Cu layers with barrier layers in between to prevent diffusion of Cu across the barrier layers. With multiple barrier layers, the amount of Cu in each Al—Cu layer may be controlled. For example, less Cu content may be included in the upper Al—Cu layers of the electrode to reduce the sheet resistance of the SAW device (improving small signal performance such as insertion loss), and more Cu content may be included in the lower Al—Cu layer(s) of the electrode to increase the stress resistance of the SAW device (improving power durability since lower layers typically experience more stress).

The detailed description set forth below in connection with the appended drawings is intended as a description of exemplary implementations and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

### Example Electroacoustic Devices

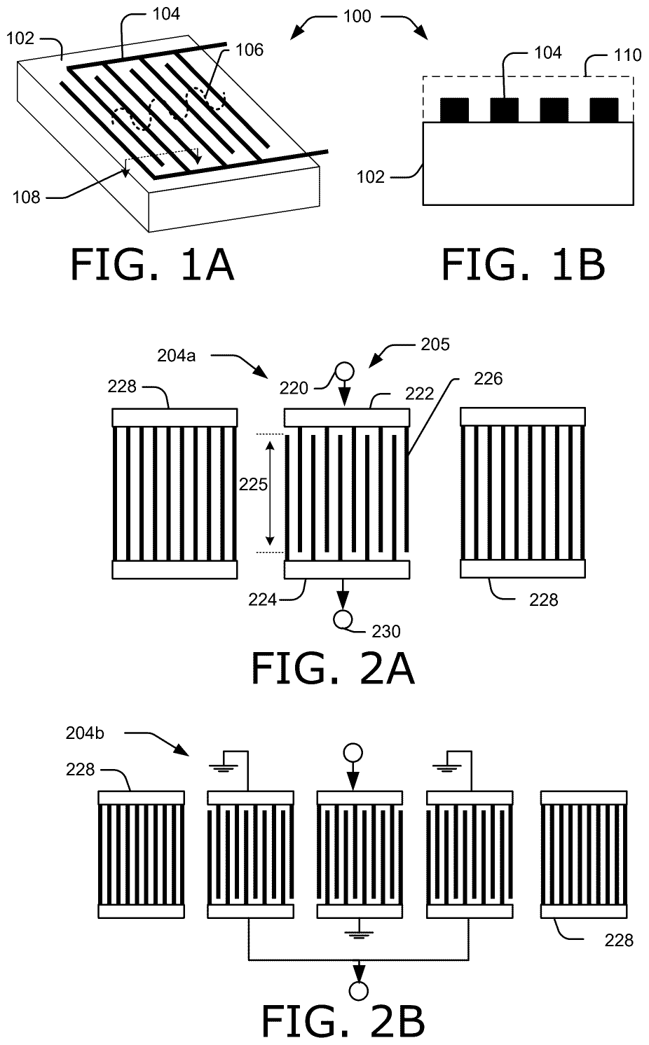

FIG. 1A is a perspective view of an example electroacoustic device 100. The electroacoustic device 100 may be configured as or be a portion of a SAW resonator. In certain descriptions herein, the electroacoustic device 100 may be referred to as a SAW resonator. However, there may be other electroacoustic device types that may be constructed based on the principles described herein.

The electroacoustic device 100 includes an electrode structure 104, that may be referred to as an interdigital transducer (IDT), on the surface of a piezoelectric material 102. The electrode structure 104 generally includes first and second comb-shaped electrode structures (conductive and generally metallic) with electrode fingers extending from two busbars towards each other arranged in an interlocking manner in between the two busbars (e.g., arranged in an interdigitated manner). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a cross-sectional view of the electroacoustic device 100 of FIG. 1A along a line segment 108 shown in FIG. 1A. The electroacoustic device 100 is illustrated by a simplified layer stack including the piezoelectric material 102 with the electrode structure 104 disposed on the piezoelectric material 102. The electrode structure 104 is electrically conductive and generally formed from metallic materials. The electrode structure 104 may alternatively be formed from materials that are electrically conductive, but non-metallic (e.g., graphene). The piezoelectric material 102 may be formed from a variety of materials such as quartz, lithium tantalate (LiTaO3), lithium niobite (LiNbO3), doped variants of these, other piezoelectric materials, or other crystals. The piezoelectric material 102 may be referred to as a “piezoelectric substrate,” but may also be referred to as a “piezoelectric layer,” such as in examples where there are additional layers below the piezoelectric material 102. It should be appreciated that more complicated layer stacks including layers of various materials may be possible within the stack. For example, optionally, a temperature compensation layer 110 denoted by the dashed lines may be disposed above the electrode structure 104. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

FIG. 2A is a top view of an example electrode structure 204a of an electroacoustic device. The electrode structure 204a has an IDT 205 that includes a first busbar 222 (e.g., first conductive segment or rail) electrically connected to a first terminal 220 and a second busbar 224 (e.g., second conductive segment or rail) spaced from the first busbar 222 and connected to a second terminal 230. A plurality of conductive fingers 226 are connected to either the first busbar 222 or the second busbar 224 in an interdigitated manner. Fingers 226 connected to the first busbar 222 extend towards the second busbar 224, but do not connect to the second busbar 224 so that there is a small gap between the ends of these fingers 226 and the second busbar 224. Likewise, fingers 226 connected to the second busbar 224 extend towards the first busbar 222, but do not connect to the first busbar 222 so that there is a small gap between the ends of these fingers 226 and the first busbar 222. Similarly, small gaps may also be formed between fingers 226 and any structure extending from the first busbar 222 or the second busbar 224 (e.g., stub fingers).

Between the busbars, there is an overlap region including a central region where a portion of one finger overlaps with a portion of an adjacent finger as illustrated by the central region 225. This central region 225 including the overlap may be referred to as the aperture, track, or active region where electric fields are produced between the fingers 226 to cause an acoustic wave to propagate in this region of the piezoelectric material 102. The periodicity of the fingers 226 is referred to as the pitch of the IDT. The pitch may be indicated in various ways. For example, in certain aspects, the pitch may correspond to a magnitude of a distance between fingers in the central region 225. This distance may be defined, for example, as the distance between center points of each of the fingers (and may be generally measured between a right (or left) edge of one finger and the right (or left) edge of an adjacent finger when the fingers have uniform width). In certain aspects, an average of distances between adjacent fingers may be used for the pitch. The frequency at which the piezoelectric material vibrates is a main resonance frequency of the electrode structure 204a. This frequency is determined at least in part by the pitch of the IDT 205 and other properties of the electroacoustic device 100.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the converted electrical signal may be provided as an output, such as to one of the first terminal 220 or the second terminal 230, while the other terminal may function as an input.

A variety of electrode structures are possible. FIG. 2A may generally illustrate a one-port configuration. Other configurations (e.g., two-port configurations) are also possible. For example, the electrode structure 204a may have an input IDT 205 where each terminal 220 and 230 functions as an input. In this event, an adjacent output IDT (not illustrated) that is positioned between the reflectors 228 and adjacent to the input IDT 205 may be provided to convert the acoustic wave propagating in the piezoelectric material 102 to an electrical signal to be provided at output terminals of the output IDT.

FIG. 2B is a top view of another example electrode structure 204b of an electroacoustic device. In this case, a dual-mode SAW (DMS) electrode structure 204b is illustrated, the DMS structure being a structure that may induce multiple resonances. The electrode structure 204b includes multiple IDTs arranged between reflectors 228 and connected as illustrated. The electrode structure 204b is provided to illustrate the variety of electrode structures that principles described herein may be applied to including the electrode structures 204a and 204b of FIGS. 2A and 2B.

It should be appreciated that while a certain number of fingers 226 are illustrated, the number of actual fingers and length(s) and width(s) of the fingers 226 and busbars may be different in an actual implementation. Such parameters depend on the particular application and desired filter characteristics. In addition, a SAW filter may include multiple interconnected electrode structures each including multiple IDTs to achieve a desired passband (e.g., multiple interconnected resonators or IDTs to form a desired filter transfer function).

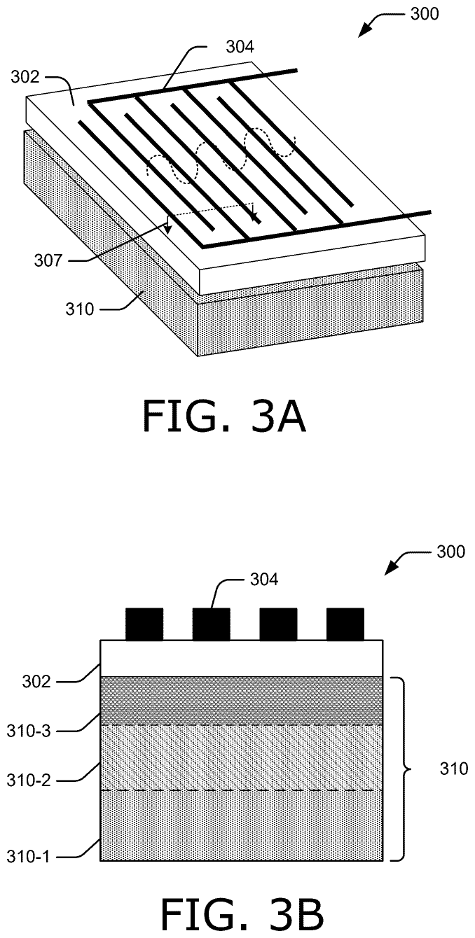

FIG. 3A is a diagram of a perspective view of another example of an electroacoustic device 300. The electroacoustic device 300 (e.g., that may be configured as or be a part of a SAW resonator) is similar to the electroacoustic device 100 of FIG. 1A but has a different layer stack. In particular, the electroacoustic device 300 includes a thin piezoelectric material 302 that is provided on a substrate 310 (e.g., silicon). The electroacoustic device 300 may be referred to as a thin-film SAW resonator (TF-SAW) in some cases. Based on the type of piezoelectric material 302 used (e.g., typically having higher coupling factors relative to the electroacoustic device 100 of FIG. 1) and a controlled thickness of the piezoelectric material 302, the particular acoustic wave modes excited may be slightly different than those in the electroacoustic device 100 of FIG. 1A. Based on the design (thicknesses of the layers, and selection of materials, etc.), the electroacoustic device 300 may have a higher Q-factor as compared to the electroacoustic device 100 of FIG. 1A. The piezoelectric material 302, for example, may be Lithium tantalate (LiTaO3) or some doped variant. Another example of a piezoelectric material 302 for FIG. 3 may be Lithium niobite (LiNbO3). In general, the substrate 310 may be substantially thicker than the piezoelectric material 302 (e.g., potentially on the order of 50 to 100 times thicker as one example—or more). The substrate 310 may include other layers (or other layers may be included between the substrate 310 and the piezoelectric material 302).

FIG. 3B is a diagram of a side view of the electroacoustic device 300 of FIG. 3A showing an exemplary layer stack (along a cross-section 307). In the example shown in FIG. 3B, the substrate 310 may include sublayers such as a substrate sublayer 310-1 (e.g., of silicon) that may have a higher resistance (e.g., relative to the other layers—high resistivity layer). The substrate 310 may further include a trap rich layer 310-2 (e.g., poly-silicon). The substrate 310 may further include a compensation layer (e.g., silicon dioxide (SiO2) or another dielectric material) that may provide temperature compensation and other properties. These sub-layers may be considered part of the substrate 310 or their own separate layers. A relatively thin piezoelectric material 302 is provided on the substrate 310 with a particular thickness for providing a particular acoustic wave mode (e.g., as compared to the electroacoustic device 100 of FIG. 1A where the thickness of the piezoelectric material 102 may not be a significant design parameter beyond a certain thickness and may be generally thicker as compared to the piezoelectric material 302 of the electroacoustic device 300 of FIGS. 3A and 3B). The electrode structure 304 is positioned above the piezoelectric material 302. In addition, in some aspects, there may be one or more layers (not shown) possible above the electrode structure 304 (e.g., such as a thin passivation layer).

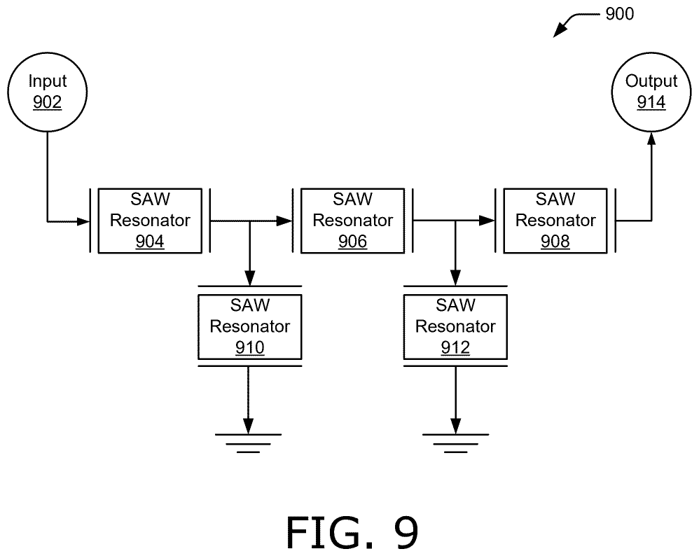

According to certain aspects of the present disclosure, the electroacoustic device 300 may be implemented in a filter or duplexer of a radio frequency (RF) circuit for use in a wireless communications device. Such a wireless communications device is described in further detail in the description of FIGS. 9-11.

### Example SAW Device With Barrier Layers Between Copper-Aluminum Layers

Electrodes for a surface acoustic wave (SAW) device (e.g., thin-film (TF) SAW device) may include a titanium (Ti) copper (Cu) aluminum (Al) stack. Cu-Al diffusion may occur after tempering during fabrication of the SAW device, resulting in phases of Al₂Cu and Cu-doped Al growing to create a grain structure. In some cases, increasing the stiffness of the SAW device may result in higher losses and higher self-heating for the SAW device, thus resulting in decreased power durability (or no improvement of power durability). Moreover, in some implementations, Al₂Cu grains may be disposed on the bottom of the electrode. However, after power loading, Al₂Cu grains increase in size due to material transport from a bottom portion to a top portion of the electrode, resulting in irreversible frequency shifts and no power durability improvement.

Certain aspects of the present disclosure are directed toward using diffusion barriers layers to prevent the movement of copper from the bottom portion to the top portion of the electrode. Multiple barrier layers resulting in multiple Al₂Cu and Cu-doped Al layers may be used, allowing for influencing the copper content in each layer. For example, higher copper content may be used in a bottom layer (e.g., use a pure Al₂Cu layer in the bottom layer) to increase the stiffness at the bottom layer that likely experiences higher stress and increases power durability. Lower copper content may be used in one or more top layers (e.g., layers above the bottom layer) to decrease the sheet resistance of the SAW device and improve small signal performance such as by decreasing insertion loss.

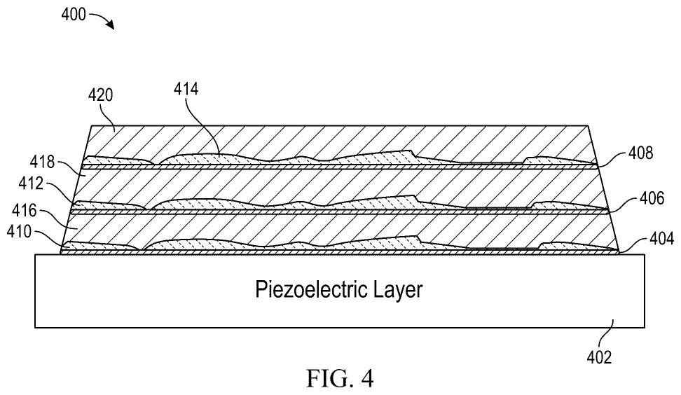

FIG. 4 illustrates an example electrode 400 for a SAW device, in accordance with certain aspects of the present disclosure. The electrode 400 may include a barrier layer 404, which may include Ti, for example, above a piezoelectric layer 402. Above the barrier layer 404 is an Al₂Cu layer 410 (e.g., grain structure), above which may be an Al layer 416 (e.g., Cu-doped Al layer). In some aspects, multiple barrier layers may be used in the electrode 400, with a barrier layer between adjacent Al₂Cu and Al layers (e.g., between an underlying Al layer and an overlying Al₂Cu layer) to prevent Cu diffusion, as described. For example, another barrier layer 406 (e.g., Ti barrier layer) may be disposed above layer 416, above which is another Al₂Cu layer 412 (e.g., grain structure) and an Al layer 418 (e.g., Cu-doped Al layer). Above layer 418 is another barrier layer 408 (e.g., Ti barrier layer), and above the barrier layer 408 is another Al₂Cu layer 414 (e.g., grain structure) and another Al layer 420 (e.g., Cu-doped Al layer). The Al₂Cu layers may be formed as Cu layers that are mixed with Al after tempering.

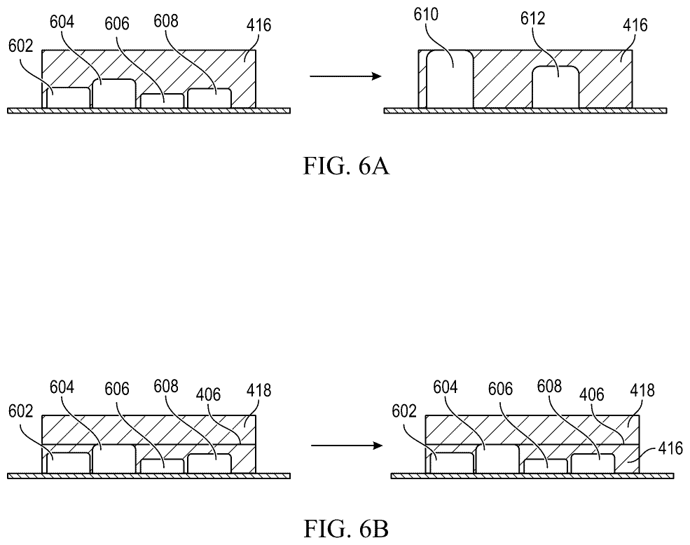

While three Al₂Cu and Al layers above three barrier layers are shown, any suitable number of Al₂Cu and Al layers and respective barrier layers may be used. The barrier layers prevent Cu diffusion to the upper Al layers. That is, the barrier layers prevent the inter-diffusion of Cu in Al as described in more detail with respect to FIG. 6.

While the barrier layers described herein are implemented using Ti, any suitable material may be used. For example, the barrier layers may be implemented with chromium (Cr), tantalum (Ta), or titanium nitride (TiN).

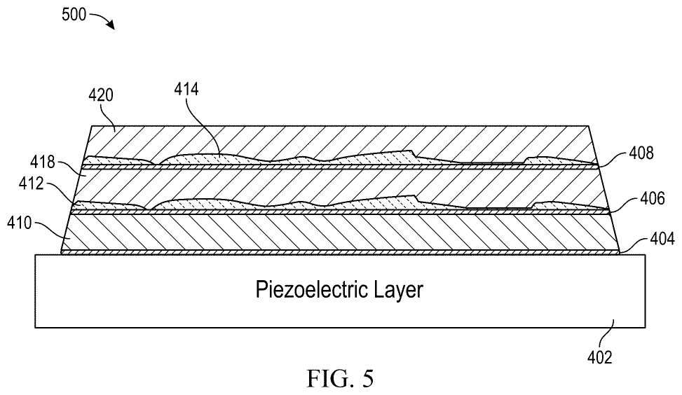

In some aspects, lower Cu content in the upper layers may be used to reduce the sheet resistance of the SAW device, providing improved small signal filtering response. In some aspects, a pure Al₂Cu layer may be used between barrier layers 404, 406, as described in more detail with respect to FIG. 5.

FIG. 5 illustrates an example electrode 500 for a SAW device, in accordance with certain aspects of the present disclosure. As shown, the entirety of the region between barrier layers 404, 406 may be an Al₂Cu layer 410. Thus, the bottom layer of the electrode 500 between barrier layers 404, 406 may have a higher Cu content, increasing the stiffness of the bottom portion of the electrode that generally experiences more stress during operation. In other words, using Al₂Cu provides a stiffer bottom layer than using a pure Cu layer, further increasing the stress resistance of the SAW device. Moreover, Al₂Cu is lighter than pure Cu. Thus, using Al₂Cu provides a lower mass load for the electrode than using a pure Cu layer.

FIG. 6A illustrates grain size growth for an electrode implemented without a barrier layer, in accordance with certain aspects of the present disclosure. As shown, after diffusion and power durability measurements, the Al₂Cu grains 602, 604, 606, 608 grow, merge, and diffuse into the Al layer 416, resulting in larger Al₂Cu grains 610, 612.

FIG. 6B illustrates an electrode implemented with a barrier layer 406, in accordance with certain aspects of the present disclosure. As shown, the barrier layer 406 prevents the growth of the grains 602, 604, 606, 608 beyond the barrier layer 406. Thus, using barrier layers, power handling of the SAW device may be improved by limiting the grain size (e.g., the size of the grain structures) and preventing redistribution of the Al₂Cu material under load.

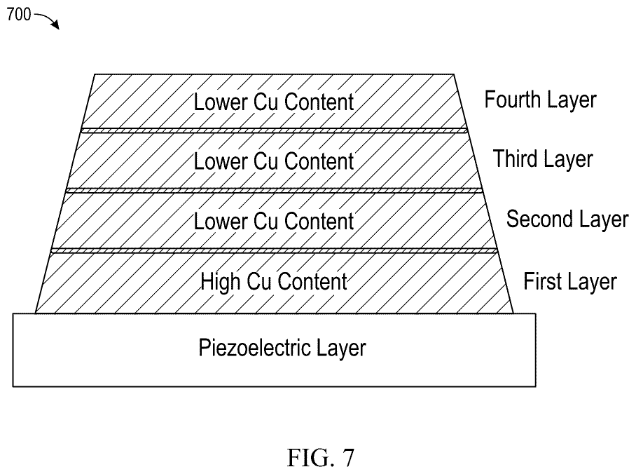

FIG. 7 illustrates an electrode 700 with four layers with varying Cu content, in accordance with certain aspects of the present disclosure. A higher Cu content (e.g., at least 8.5% of the layer volume) may be used for the first layer and lower Cu content may be used in the upper layers (e.g., second, third, and fourth layers). In some cases, the bottommost layer (layer 1) of the electrode may have the most Cu content, and the Cu content may decrease in each higher layer so that the topmost layer (fourth layer) of the electrode has the least Cu content.

Certain aspects of the present disclosure provide increased power durability, reduced self-heating, and reduced acoustic losses due to the barrier layers maintaining the lower grain size. The lifetime of the SAW device may be increased by avoiding (or at least reducing) any frequency shift for the device.

### Example Operations for Fabricating a SAW Device

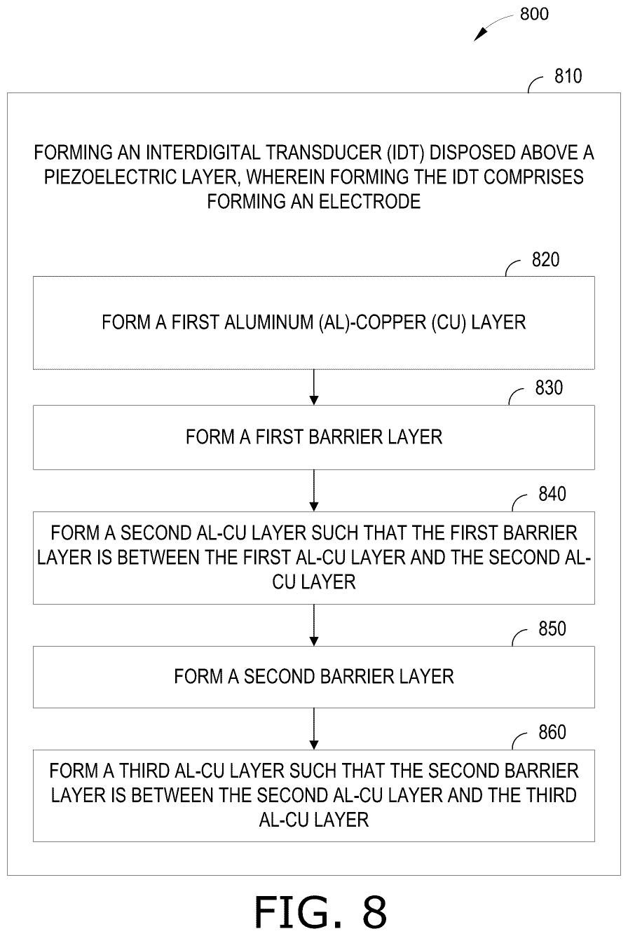

FIG. 8 is a block diagram of example operations 800 for fabricating a surface acoustic wave (SAW) device. The operations 800 may be performed by a manufacturing facility.

At block 810, the facility forms an interdigital transducer (IDT) disposed above a piezoelectric layer (e.g., piezoelectric layer 402 of FIG. 4). Forming the IDT may include forming an electrode (e.g., electrode 400 or electrode 500). The facility forms the electrode by, at block 820, forming a first aluminum (Al)-copper (Cu) layer (e.g., Al₂Cu layer 410). To form the electrode, the facility may, at block 830, form a first barrier layer (e.g., barrier layer 406), and at block 840, form a second Al—Cu layer (e.g., Al₂Cu layer 412) such that the first barrier layer is between the first Al—Cu layer and the second Al—Cu layer. To form the electrode, the facility may, at block 850, form a second barrier layer (e.g., barrier layer 408), and at block 860, form a third Al—Cu layer (e.g., Al₂Cu layer 414) such that the second barrier layer is between the second Al—Cu layer and the third Al—Cu layer.

In some aspects, the facility may form an Al layer (e.g., Al layer 416 and/or Al layer 418) above the first Al—Cu layer or the second Al—Cu layer, such that the Al layer is disposed between: (i) the first Al—Cu layer and the first barrier layer or (ii) the second Al—Cu layer and the second barrier layer. The Al layer may include a Cu-doped Al layer.

In some aspects, at least one of the first barrier layer or the second barrier layer comprises titanium, chromium, tantalum, tungsten, titanium nitride, chromium nitride, tantalum nitride, or tungsten nitride. In some aspects, at least one of the first Al—Cu layer, the second Al—Cu layer, or the third Al—Cu layer comprises a grain structure.

The facility may form a third barrier layer (e.g., barrier layer 404) above the piezoelectric layer before forming the first Al—Cu layer. The first Al—Cu layer may be formed to fill an entirety of a region between the third barrier layer and the first barrier layer.

In some aspects, an amount of Cu content between the piezoelectric layer and the first barrier layer is more than an amount of Cu content between the first barrier layer and the second barrier layer. In some aspects, each of the first Al—Cu layer, the second Al—Cu layer, and the third Al—Cu layer comprises an Al₂Cu layer.

### Example Integration Into a Filter and Wireless Communications Device

FIG. 9 is a schematic diagram of an electroacoustic filter circuit 900 that may include an electroacoustic device implemented using electrode 400, electrode 500, or electrode 700. The filter circuit 900 provides one example of where the disclosed SAW devices may be used. The filter circuit 900 includes an input terminal 902 and an output terminal 914. Between the input terminal 902 and the output terminal 914, a ladder-type network of SAW resonators is provided. The filter circuit 900 includes a first SAW resonator 904, a second SAW resonator 906, and a third SAW resonator 908 all electrically connected in series between the input terminal 902 and the output terminal 914. A fourth SAW resonator 910 (e.g., a shunt resonator) has a first terminal connected to a node between the first SAW resonator 904 and the second SAW resonator 906 and has a second terminal connected to a reference potential node (e.g., electric ground) for the filter circuit 900. A fifth SAW resonator 912 (e.g., a shunt resonator) has a first terminal connected to a node between the second SAW resonator 906 and the third SAW resonator 908 and has a second terminal connected to the reference potential node. The electroacoustic filter circuit 900 may, for example, be a bandpass filter circuit having a passband with a selected frequency range (e.g., in a range between 500 MHz and 6 GHz).

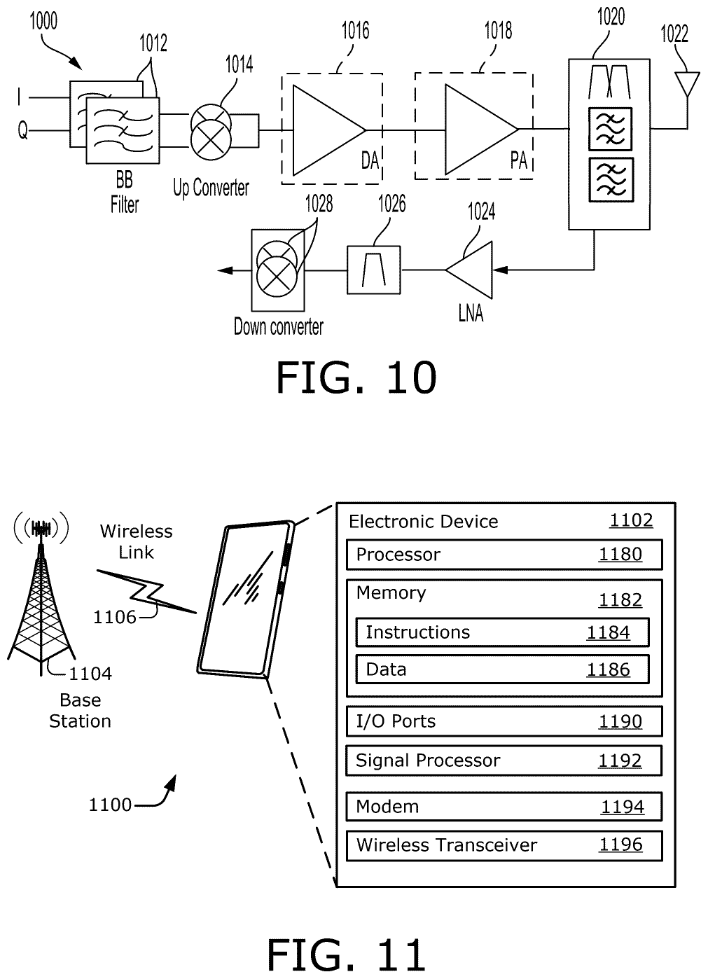

FIG. 10 is a functional block diagram of at least a portion of an example simplified wireless transceiver circuit 1000 in which the filter circuit 900 of FIG. 9 may be employed. The transceiver circuit 1000 is configured to receive signals/information for transmission (shown as in-phase (I) and quadrature (Q) values) which is provided to one or more baseband (BB) filters 1012. The filtered output is provided to one or more mixers 1014 for upconversion to radio frequency (RF) signals. The output from the one or more mixers 1014 may be provided to a driver amplifier (DA) 1016 whose output may be provided to a power amplifier (PA) 1018 to produce an amplified signal for transmission. The amplified signal is output to the antenna 1022 through one or more filters 1020 (e.g., duplexers if used as a frequency division duplex transceiver or other filters). The one or more filters 1020 may include the filter circuit 900 of FIG. 9.

The antenna 1022 may be used for both wirelessly transmitting and receiving data. The transceiver circuit 1000 includes a receive path through the one or more filters 1020 to be provided to a low noise amplifier (LNA) 1024 and a further filter 1026 and then down converted from the receive frequency to a baseband frequency through one or more mixer circuits 1028 before the signal is further processed (e.g., provided to an analog-to-digital converter (ADC) and then demodulated or otherwise processed in the digital domain). There may be separate filters for the receive circuit (e.g., may have a separate antenna or have separate receive filters) that may be implemented using the filter circuit 900 of FIG. 9.

FIG. 11 is a diagram of an environment 1100 that includes an electronic device 1102, in which aspects of the present disclosure may be practiced. In the environment 1100, the electronic device 1102 communicates with a base station 1104 (e.g., a gNB) through a wireless link 1106. As shown, the electronic device 1102 is depicted as a smartphone. However, the electronic device 1102 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, wearable device, sensor or security device, asset tracker, and so forth.

The base station 1104 communicates with the electronic device 1102 via the wireless link 1106, which may be implemented as any suitable type of wireless link. Although depicted as a base station tower of a cellular radio network, the base station 1104 may represent or be implemented as another device, such as a satellite, terrestrial broadcast tower, access point, peer-to-peer device, mesh network node, fiber optic line, another electronic device generally as described above, and so forth. Hence, the electronic device 1102 may communicate with the base station 1104 or another device via a wired connection, a wireless connection, or a combination thereof. The wireless link 1106 can include a downlink of data or control information communicated from the base station 1104 to the electronic device 1102 and an uplink of other data or control information communicated from the electronic device 1102 to the base station 1104. The wireless link 1106 may be implemented using any suitable communication protocol or standard, such as 3rd Generation Partnership Project Long-Term Evolution (3GPP LTE), 3GPP NR 5G, IEEE 802.11, IEEE 802.16, Bluetooth™, and so forth.

The electronic device 1102 includes a processor 1180 and a memory 1182. The memory 1182 may be or form a portion of a computer-readable storage medium. The processor 1180 may include any type of processor, such as an application processor or a multi-core processor, that is configured to execute processor-executable instructions (e.g., code) stored by the memory 1182. The memory 1182 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 1182 is implemented to store instructions 1184, data 1186, and other information of the electronic device 1102, and thus when configured as or part of a computer-readable storage medium, the memory 1182 does not include transitory propagating signals or carrier waves.

The electronic device 1102 may also include input/output ports 1190. The I/O ports 1190 enable data exchanges or interaction with other devices, networks, or users or between components of the device.

The electronic device 1102 may further include a signal processor (SP) 1192 (e.g., such as a digital signal processor (DSP)). The signal processor 1192 may function similar to the processor and may be capable of executing instructions and/or processing information in conjunction with the memory 1182.

For communication purposes, the electronic device 1102 also includes a modem 1194, a wireless transceiver 1196, and an antenna (not shown). The wireless transceiver 1196 provides connectivity to respective networks and other electronic devices connected therewith using radio frequency (RF) wireless signals and may include the transceiver circuit 1000 of FIG. 10. The wireless transceiver 1196 may facilitate communication over any suitable type of wireless network, such as a wireless local area network (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

### Example Aspects

In addition to the various aspects described above, specific combinations of aspects are within the scope of the disclosure, some of which are detailed in the clauses below:
Aspect 1: A surface acoustic wave (SAW) device comprising: a piezoelectric layer; and an interdigital transducer (IDT) disposed above the piezoelectric layer and comprising an electrode including: a first aluminum (Al)-copper (Cu) layer; a second Al—Cu layer; a first barrier layer between the first Al—Cu layer and the second Al—Cu layer; a third Al—Cu layer; and a second barrier layer between the second Al—Cu layer and the third Al—Cu layer.
Aspect 2: The SAW device of Aspect 1, wherein at least one of the first barrier layer or the second barrier layer is implemented using titanium.
Aspect 3: The SAW device of Aspect 1 or 2, wherein the electrode further comprises at least one of: a first Al layer between the first Al—Cu layer and the first barrier layer; or a second Al layer between the second Al—Cu layer and the second barrier layer.
Aspect 4: The SAW device of Aspect 3, wherein at least one of the first Al layer or the second Al layer comprises a Cu-doped Al layer.
Aspect 5: The SAW device according to any of Aspects 1-4, wherein the electrode further comprises a third barrier layer between the piezoelectric layer and the first Al—Cu layer.
Aspect 6: The SAW device of Aspect 5, wherein the first Al—Cu layer fills an entirety of a region between the third barrier layer and the first barrier layer.
Aspect 7: The SAW device according to any of Aspects 1-6, wherein a first magnitude of Cu content between the piezoelectric layer and the first barrier layer is more than a second magnitude of Cu content between the first barrier layer and the second barrier layer.
Aspect 8: The SAW device according to any of Aspects 1-7, wherein each of the first Al—Cu layer, the second Al—Cu layer, and the third Al—Cu layer comprises an Al2Cu layer.
Aspect 9: The SAW device according to any of Aspects 1-8, wherein at least one of the first barrier layer or the second barrier layer is implemented using titanium, chromium, tantalum, tungsten, titanium nitride, chromium nitride, tantalum nitride, or tungsten nitride.
Aspect 10: The SAW device according to any of Aspects 1-9, wherein at least one of the first Al—Cu layer, the second Al—Cu layer, or the third Al—Cu layer comprises a grain structure.
Aspect 11: A method of fabricating a surface acoustic wave (SAW) device, the method comprising forming an interdigital transducer (IDT) disposed above a piezoelectric layer, wherein forming the IDT comprises forming an electrode and wherein forming the electrode comprises: forming a first aluminum (Al)-copper (Cu) layer; forming a first barrier layer; forming a second Al—Cu layer such that the first barrier layer is between the first Al—Cu layer and the second Al—Cu layer; forming a second barrier layer; and forming a third Al—Cu layer such that the second barrier layer is between the second Al—Cu layer and the third Al—Cu layer.
Aspect 12: The method of Aspect 11, wherein forming the electrode further comprises forming a third barrier layer above the piezoelectric layer before forming the first Al—Cu layer, such that the third barrier layer is disposed between the piezoelectric layer and the first Al—Cu layer.
Aspect 13: The method of Aspect 12, wherein the first Al—Cu layer is formed to fill an entirety of a region between the third barrier layer and the first barrier layer.
Aspect 14: The method according to any of Aspects 11-13, wherein a first magnitude of Cu content between the piezoelectric layer and the first barrier layer is more than a second magnitude of Cu content between the first barrier layer and the second barrier layer.
Aspect 15: The method according to any of Aspects 11-14, wherein each of the first Al—Cu layer, the second Al—Cu layer, and the third Al—Cu layer comprises an Al2Cu layer.
Aspect 16: The method according to any of Aspects 11-15, wherein at least one of the first barrier layer or the second barrier layer comprises titanium, chromium, tantalum, tungsten, titanium nitride, chromium nitride, tantalum nitride, or tungsten nitride.
Aspect 17: The method according to any of Aspects 11-16, wherein forming the electrode further comprises forming at least one of: a first Al layer above the first Al—Cu layer before forming the first barrier layer, such that the first Al layer is disposed between the first Al—Cu layer and the first barrier layer; or a second Al layer above the second Al—Cu layer before forming the second barrier layer, such that the second Al layer is disposed between the second Al—Cu layer and the second barrier layer.
Aspect 18: The method of Aspect 17, wherein at least one of the first Al layer or the second Al layer comprises a Cu-doped Al layer.
Aspect 19: The method according to any of Aspects 11-18, wherein at least one of the first Al—Cu layer, the second Al—Cu layer, or the third Al—Cu layer comprises a grain structure.
Aspect 20: A wireless device comprising: a radio frequency (RF) circuit; and a surface acoustic wave (SAW) filter coupled to the RF circuit, the SAW filter comprising: a piezoelectric layer; and an interdigital transducer (IDT) disposed above the piezoelectric layer and comprising an electrode including: a first aluminum (Al)-copper (Cu) layer; a second Al—Cu layer; a first barrier layer between the first Al—Cu layer and the second Al—Cu layer; a third Al—Cu layer; and a second barrier layer between the second Al—Cu layer and the third Al—Cu layer.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

By way of example, an element, or any portion of an element, or any combination of elements described herein may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoCs), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuit.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. A surface acoustic wave (SAW) device comprising:
a piezoelectric layer; and
an interdigital transducer (IDT) disposed above the piezoelectric layer and comprising an electrode including:
a first aluminum (Al)-copper (Cu) layer;
a second Al—Cu layer;
a first barrier layer between the first Al—Cu layer and the second Al—Cu layer;
a third Al—Cu layer; and
a second barrier layer between the second Al—Cu layer and the third Al—Cu layer.

2. The SAW device of claim 1, wherein at least one of the first barrier layer or the second barrier layer is implemented using titanium.

3. The SAW device of claim 1, wherein the electrode further comprises at least one of:
a first Al layer between the first Al—Cu layer and the first barrier layer; or
a second Al layer between the second Al—Cu layer and the second barrier layer.

4. The SAW device of claim 3, wherein at least one of the first Al layer or the second Al layer comprises a Cu-doped Al layer.

5. The SAW device of claim 1, wherein the electrode further comprises a third barrier layer between the piezoelectric layer and the first Al—Cu layer.

6. The SAW device of claim 5, wherein the first Al—Cu layer fills an entirety of a region between the third barrier layer and the first barrier layer.

7. The SAW device of claim 1, wherein a first magnitude of Cu content between the piezoelectric layer and the first barrier layer is more than a second magnitude of Cu content between the first barrier layer and the second barrier layer.

8. The SAW device of claim 1, wherein each of the first Al—Cu layer, the second Al—Cu layer, and the third Al—Cu layer comprises an Al₂Cu layer.

9. The SAW device of claim 1, wherein at least one of the first barrier layer or the second barrier layer is implemented using titanium, chromium, tantalum, tungsten, titanium nitride, chromium nitride, tantalum nitride, or tungsten nitride.

10. The SAW device of claim 1, wherein at least one of the first Al—Cu layer, the second Al—Cu layer, or the third Al—Cu layer comprises a grain structure.

11. A method of fabricating a surface acoustic wave (SAW) device, the method comprising forming an interdigital transducer (IDT) disposed above a piezoelectric layer, wherein forming the IDT comprises forming an electrode and wherein forming the electrode comprises:
forming a first aluminum (Al)-copper (Cu) layer;
forming a first barrier layer;
forming a second Al—Cu layer such that the first barrier layer is between the first Al—Cu layer and the second Al—Cu layer;
forming a second barrier layer; and
forming a third Al—Cu layer such that the second barrier layer is between the second Al—Cu layer and the third Al—Cu layer.

12. The method of claim 11, wherein forming the electrode further comprises forming a third barrier layer above the piezoelectric layer before forming the first Al—Cu layer, such that the third barrier layer is disposed between the piezoelectric layer and the first Al—Cu layer.

13. The method of claim 12, wherein the first Al—Cu layer is formed to fill an entirety of a region between the third barrier layer and the first barrier layer.

14. The method of claim 11, wherein a first magnitude of Cu content between the piezoelectric layer and the first barrier layer is more than a second magnitude of Cu content between the first barrier layer and the second barrier layer.

15. The method of claim 11, wherein each of the first Al—Cu layer, the second Al—Cu layer, and the third Al—Cu layer comprises an Al₂Cu layer.

16. The method of claim 11, wherein at least one of the first barrier layer or the second barrier layer comprises titanium, chromium, tantalum, tungsten, titanium nitride, chromium nitride, tantalum nitride, or tungsten nitride.

17. The method of claim 11, wherein forming the electrode further comprises forming at least one of:
a first Al layer above the first Al—Cu layer before forming the first barrier layer, such that the first Al layer is disposed between the first Al—Cu layer and the first barrier layer; or
a second Al layer above the second Al—Cu layer before forming the second barrier layer, such that the second Al layer is disposed between the second Al—Cu layer and the second barrier layer.

18. The method of claim 17, wherein at least one of the first Al layer or the second Al layer comprises a Cu-doped Al layer.

19. The method of claim 11, wherein at least one of the first Al—Cu layer, the second Al—Cu layer, or the third Al—Cu layer comprises a grain structure.

20. A wireless device comprising:
a radio frequency (RF) circuit; and
a surface acoustic wave (SAW) filter coupled to the RF circuit, the SAW filter comprising:
a piezoelectric layer; and
an interdigital transducer (IDT) disposed above the piezoelectric layer and comprising an electrode including:
a first aluminum (Al)-copper (Cu) layer;
a second Al—Cu layer;
a first barrier layer between the first Al—Cu layer and the second Al—Cu layer;
a third Al—Cu layer; and
a second barrier layer between the second Al—Cu layer and the third Al—Cu layer.
